(19) United States
(12) Patent Application Publication
(10) Pub. No.: US 2026/0076019 A1
(43) Pub. Date: Mar. 12, 2026

(54) OPTOELECTRONIC COMPONENT WITH INTEGRATED APERTURE MASK

(71) Applicant: Saxo Consulting GmbH, Dresden (DE)

(72) Inventors: Rico MEERHEIM, Dresden (DE); David WYNANDS, Dresden (DE); Matthias JAHNEL, Dresden (DE); Robert BRÜCKNER, Dresden (DE)

(73) Assignee: Saxo Consulting GmbH, Dresden (DE)

(21) Appl. No.: 19/108,078

(22) PCT Filed: Aug. 29, 2023
(86) PCT No.: PCT/EP2023/073624

§ 371 Date: Feb. 28, 2025

(30) Foreign Application Priority Data
Sep. 9, 2022 (DE) 10 2022 122 954.8

(51) Int. Cl. H10K 30/88; H10K 30/60

(52) U.S. Cl. CPC H10K 30/88; H10K 30/60

(57) ABSTRACT

In order to shade the inhomogeneous edge region (503) of organic optoelectronic components (1, 1′), which region causes artefacts in the photosignal of the components, it is known practice, after the deposition of all the layers of a component, for an aperture mask to be adhesively bonded on the encapsulation of said component. The alignment of the aperture mask constitutes not only an additional work step, but also a considerable source of error. The invention overcomes these disadvantages by virtue of the fact that at least one radiation-repellent layer (3) which covers the edge region (503) of a photodetector (5) of the optoelectronic component (1, 1′), but not more than 30% of the selective area (502) thereof, is deposited, preferably by means of a coating method, directly onto a radiation incoupling layer (4) covering the entire sensitive area (501), such that the at least one radiation-repellent layer (3) is integrally bonded to the radiation incoupling layer (4).

The invention relates to an optoelectronic component in the form of a layer stack, comprising a photodetector having a sensitive area which is formed of a selective area and an edge region surrounding the selective area, wherein the photodetector comprises at least one photoactive layer between two spaced-apart electrodes, wherein the first electrode, which is arranged in front of the second electrode in the illumination direction, is at least semi-transparent for electromagnetic radiation with wavelengths to be detected.

Photodetectors are used for the qualitative and/or quantitative detection of electromagnetic radiation. The detection may take place in a spectrally selective manner, in which case radiation is detected in a predefined, specific wavelength range. In the photoactive layer of a photodetector, electromagnetic radiation is converted into charge carrier pairs consisting of electrons and defect electrons (holes). Organic photodetectors typically have a photoactive layer that contains an organic electron donor compound (donor compound or donor, D, for short), i.e., a material that gives up electrons and receives defect electrons or holes, and an organic electron acceptor compound (acceptor compound or acceptor, A, for short), i.e., a material that receives electrons. The separation of the charge carrier pairs, which is necessary in order to generate an electrical signal, may take place at the interface between the donor and the acceptor. Once a charge carrier pair has been separated, the holes in the donor and the electrons in the acceptor are transported to the electrodes.

The photoactive layer of the photodetector may contain, for example, a mixed layer formed of a donor material and an acceptor material, often referred to as a “D: A blend” or “bulk heterojunction blend.”

A photodetector is usually designed to detect one specific wavelength or a plurality of specific wavelengths or one or more specific wavelength ranges of the total spectrum of electromagnetic radiation, these being referred to below as “wavelengths to be detected” or “wavelength range to be detected.” The wavelengths to be detected are determined, for example, by the band gap between the highest occupied orbital (HOMO) and the lowest unoccupied orbital (LUMO) of the donor compound and the acceptor compound. Direct optical excitation of an intermolecular charge transfer state (CT state) at an interface between a donor compound and an acceptor compound may also take place. Taken in isolation, the donor compound and the acceptor compound do not necessarily have to absorb in the wavelength range to be detected, i.e., the band gap between the highest occupied orbital (HOMO) and the lowest unoccupied orbital (LUMO) of both the donor compound and the acceptor compound do not necessarily have to correspond to an energy equivalent in the wavelength range to be detected. Instead, the energy of a photon of electromagnetic radiation that can be absorbed via the CT state substantially corresponds to the difference between the higher-energy HOMO of one compound and the lower-energy LUMO of the other compound, or is even slightly lower than this difference.

Lateral deviations in the thickness of the photoactive layer of a photodetector may lead to artefacts in the spectral response of the photodetector, especially when the photoactive layer thereof is arranged between two mirror surfaces, i.e., within an optical microcavity; this may in turn lead to inaccuracies or errors in the evaluation of the photosignal. Here, the “thickness” of a layer is the extent of the layer in the direction parallel to the surface normal of the layer, which substantially also corresponds to the illumination direction.

Accordingly, the “lateral direction” refers to a direction perpendicular to the direction in which the thickness is determined.

The illumination direction corresponds to the main direction of incidence of the to-be-detected electromagnetic radiation on the optoelectronic component after having interacted with the sample to be examined.

When depositing organic layers, e.g., by means of a PVD method such as thermal vapor deposition, uncontrollable thickness deviations in the edge region of the photoactive layer occur particularly frequently, since the organic layer cannot be deposited in such a way as to form with an ideally uniform, e.g., ideally cuboid-shaped, cross-section. The edge region comprises a transition region until the complete, desired layer thickness is reached, wherein the layer thickness usually increases, not necessarily linearly, but homogeneously. The region in which thickness deviations occur during deposition usually has a lateral extent of a few tens of μm to approximately 150 μm—for example, 50 μm. However, layer deposition masks can typically be aligned only with an accuracy of a few hundred μm, e.g., 200 μm, so that an undesirable variation in layer thickness may occur due to an offset between deposition masks in an edge region having a lateral extent of between approximately 50 μm to approximately 300 μm. These deviations may lead to artefacts and thus may negatively affect the photosignal. Particularly in the case of photodetectors with optical microcavities, an undesired, non-selective portion of the photosignal may also occur due to irradiation into areas of the photodetector that are not arranged between the mirror surfaces. In order to avoid the aforementioned undesired effects, it is known practice for the edge region to be covered by a mask that is opaque to radiation in the wavelength range to be detected. The mask usually consists of a metallic material and has apertures in the shape and dimensions of the selective area of the photodetector, so as not to substantially reduce the size of the selective area of the photodetector and thus the radiation power available for detection.

The aperture masks known from the prior art are arranged on the photodetector subsequently, i.e., following complete deposition of all the layers of the photodetector and encapsulation thereof, and must therefore be placed and attached, e.g., adhesively bonded to the encapsulation, with micrometer accuracy.

One disadvantage of this is the high post-processing effort that occurs after the photodetectors have been manufactured, wherein the placement of the aperture mask also constitutes a significant source of error.

The object of the invention is therefore to overcome the aforementioned disadvantages and to provide an optoelectronic component which does not require any post-processing effort in terms of subsequent placement of an aperture mask.

The object is achieved by an optoelectronic component according to claim 1, an associated arrangement of optoelectronic components according to claim 5, a method for producing an optoelectronic component according to claim 6, and the use of the optoelectronic component or arrangement according to claim 7. Developments of the invention are specified in dependent claims.

The invention achieves this object in that the aperture mask is no longer arranged externally on the encapsulated layer stack of the photodetector, but instead is integrated into the layer stack.

The optoelectronic component according to the invention in the form of a layer stack contains at least one photodetector which comprises at least one photoactive layer arranged between two spaced-apart electrodes. The photoactive layer is illuminated through the first of the two electrodes, for which reason the first electrode is designed to be at least semi-transparent for electromagnetic radiation in the wavelength range to be detected. The sensitive area of the photodetector is divided into a selective area and an edge region surrounding the area in a frame-like manner.

According to the invention, arranged in front of the photodetector is at least one radiation incoupling layer, which completely covers the sensitive area of the photodetector, i.e., both the selective area and the edge region. Arranged in front of the radiation incoupling layer is at least one radiation-repellent layer. In the sense of the invention, “radiation-repellent” means that the layer has a high degree of absorption or preferably a high degree of reflection for the electromagnetic radiation with wavelengths to be detected that impinges on the optoelectronic component, preferably a degree of absorption or a degree of reflection of at least 80%, particularly preferably at least 90%, very particularly preferably at least 95%. The at least one radiation-repellent layer is integrally bonded to the radiation incoupling layer. In a preferred embodiment of the invention, the at least one radiation-repellent layer is inseparably bonded to the radiation incoupling layer by means of a coating method-for example, by means of thermal vapor deposition. The at least one radiation-repellent layer is arranged such that it covers at least portions of the edge region of the photodetector, but not more than 30% of the selective area thereof. It is clear to a person skilled in the art that typical alignment accuracies of the masks for layer deposition do not make it possible to prevent a small degree of coverage of the selective area. Preferably, the at least one radiation-repellent layer covers no more than 20% of the selective area of the photodetector, particularly preferably no more than 10%.

An optoelectronic component according to the invention may have a plurality of radiation-repellent layers arranged laterally offset from one another.

The radiation-repellent layer shields the covered edge region of the photodetector against electromagnetic radiation, so that it substantially does not contribute to signal generation in the photodetector. The radiation-repellent layer thus provides a defined aperture through which the selective area of the photodetector is illuminated, wherein the photoactive layer of the photodetector beneath the selective area has a sufficiently homogeneous thickness.

In the sense of the invention, the “selective area” of the photodetector is understood to mean the laterally extended area of the photodetector, which area is sensitive to the incident electromagnetic radiation with wavelengths to be detected and beneath which the photoactive layer of the photodetector has a sufficiently homogeneous thickness, so that no artefacts are caused in the spectral response due to thickness deviations.

In the sense of the invention, the “sensitive area” of the photodetector is the laterally extended area of the photodetector, which area is sensitive to the incident electromagnetic radiation with wavelengths to be detected and within which incident electromagnetic radiation leads to a measurable photosignal. This measurable photosignal may be caused by electromagnetic radiation with wavelengths to be detected and also may contain an undesired component caused by electromagnetic radiation with wavelengths other than those to be detected.

In this sense, the “edge region” corresponds to the portion of the sensitive area of the photodetector that cannot be assigned to the selective area.

The direction or location specifications “in front of,” “after,” and “beneath” relate to the illumination direction. Therefore, if a first layer is arranged “in front of” a second layer, the incident electromagnetic radiation impinges firstly on the first layer and then on the second layer.

An optoelectronic component or an arrangement of a plurality of optoelectronic components may be assigned an illumination system which emits electromagnetic radiation-for example, with wavelengths to be detected. The electromagnetic radiation is detected by the optoelectronic component either after reflection at the sample to be examined or after transmission therethrough.

One of the two electrodes of the optoelectronic component according to the invention, referred to as the “first electrode” in the sense of the invention, is designed such that the optoelectronic component can be illuminated through this electrode. For example, the first electrode is designed to be transparent at least for the wavelengths to be detected.

If the first electrode has a reflective area which constitutes a mirror surface of an optical microcavity, the first electrode may be designed to be semi-transparent at least in the wavelength range to be detected, so that at least radiation in the wavelength range to be detected can be transmitted through the first electrode, but is also reflected by the reflective area of the electrode.

Depending upon the illumination direction and the configuration of the optoelectronic component, the first electrode may be the bottom electrode, i.e., the electrode arranged closest to the substrate, or the top electrode, i.e., the electrode arranged further from the substrate.

The first and the second electrodes may consist of a layer system formed of a plurality of individual layers arranged one above the other. For example, one electrode or both electrodes may have a mirror layer and/or a layer for improving the nucleation behavior of adjacent layers.

An optoelectronic component according to the invention may be connected to a readout unit for reading out-preferably also for further processing-electrical signals generated by the optoelectronic component.

The optoelectronic component according to the invention may be arranged on a substrate, which may be rigid, partially flexible, or flexible. Depending upon the direction from which the optoelectronic component is to be illuminated, it is expedient to make the substrate transparent at least for the wavelengths to be detected, in order to be able to illuminate the optoelectronic component through the substrate.

The advantage of the optoelectronic component according to the invention is that the aperture mask in the form of the at least one radiation-repellent layer does not have to be placed externally on the optoelectronic component and aligned, but, instead, the aperture mask is inseparably integrated into the optoelectronic component as an integral part of the layer stack. Therefore, there is no need for any post-processing effort in terms of subsequently arranging the aperture mask on the layer stack, e.g., on the encapsulation, of the optoelectronic component.

An additional benefit of the invention is that the radiation incoupling layer, which is arranged between the first electrode of the photodetector and the radiation-repellent layer in order to electrically isolate these from each other, leads to an increase in the photosignal by influencing the distribution of the optical field and the amplitude thereof in the photoactive layer. In addition, the external reflection of the first electrode can be reduced by the radiation incoupling layer.

Materials suitable for the radiation incoupling layer are those that have the highest possible transparency in the wavelength range to be detected and a refractive index suitable for increasing the photosignal, such as, for example, but not exclusively, organic semiconductor materials such as Alq₃ (tris(8-hydroxyquinoline)aluminum(III)), BF-DPB (N,N′-bis(9,9-dimethyl-9H-fluoren-2-yl)-N,N′-diphenylbenzidine), C₆₀, etc.

The at least one radiation-repellent layer preferably consists of a metallic material, particularly preferably of aluminum. Alternatively, the at least one radiation-repellent layer preferably consists of a dielectric mirror material.

Preferably, a radiation-repellent layer projects beyond the portion of the edge region of the photodetector that it covers, typically by a few hundred μm, e.g., 250 μm, but without significantly protruding into the selective area of the photodetector, i.e., for example, without reducing the size of the selective area by more than 30%, preferably without reducing the size thereof by more than 20%, particularly preferably without reducing the size thereof by more than 10%.

Preferably, the radiation incoupling layer projects beyond the at least one radiation-repellent layer, typically by a few hundred μm—for example, 250 μm.

The photodetector may comprise further layers, which are arranged between the two electrodes of the photodetector. Preferably, the photodetector has charge carrier transport layers as further layers, e.g., a hole transport layer (HTL) arranged between the photoactive layer and the hole-collecting electrode, typically the top electrode, and/or an electron transport layer (ETL) arranged between the photoactive layer and the electron-collecting electrode, typically the bottom electrode. In order to improve the transport properties, often, the ETL has an n-doping, and the HTL has a p-doping. In order to improve the extraction of charge carriers from the photoactive layer, an undoped transport layer may be inserted between the photoactive layer and a doped transport layer.

The optoelectronic component may have an encapsulation in order to reduce the effects of harmful environmental influences. The layer structure of the optoelectronic component is sealed off with respect to the environment by means of the encapsulation and the substrate. The entire layer structure of the optoelectronic component according to the invention is located within the encapsulation.

In addition to those already mentioned, an optoelectronic component according to the invention may also comprise further layers-for example, optically transparent spacer layers.

There are two main configurations for arranging the layer structure of an optoelectronic component according to the invention, which substantially result from the illumination direction of the incident electromagnetic radiation.

In the “bottom illumination” configuration, the optoelectronic component is illuminated through the substrate and the bottom electrode. The at least one radiation-repellent layer may be deposited, e.g., vapor-deposited, directly onto a substrate—for example, made of glass or plastic. Deposition takes place only at those locations where at least portions of the edge region of the photodetector form and, in the context of the alignment accuracy of the deposition masks, not where the selective area of the photodetector is arranged. This is followed by the deposition of the radiation incoupling layer, which occurs both on the radiation-repellent layer and on the substrate. The first, at least semi-transparent electrode—here, the bottom electrode—as well as the further layers of the photodetector, are then arranged, ending with the second electrode—here, the top electrode—which may be opaque in the wavelength range to be detected.

In the “top illumination” configuration, in which the incident electromagnetic radiation enters the photodetector through the top electrode, the layers of the optoelectronic component are deposited opposite to the illumination direction. Firstly, the second electrode—here, the bottom electrode—of the photodetector is deposited on the substrate, and the remaining layers of the photodetector are deposited on the second electrode, ending with the first, at least semi-transparent electrode—here, the top electrode. The radiation incoupling layer is arranged on the latter, covering the selective area and the edge region of the photodetector. In the edge region of the photodetector, the radiation-repellent layer is arranged on the radiation incoupling layer. Since illumination takes place, not through the substrate, but instead through the top electrode, the latter, just like the bottom electrode, may be opaque in the wavelength range to be detected.

A plurality of optoelectronic components according to the invention can be combined to form an arrangement—for example, in the form of a grid or line or in any other configuration. Preferably, the optoelectronic components according to the invention in the arrangement differ from one another in terms of their wavelengths to be detected, i.e., the components are optimized to detect wavelength ranges that differ from one another. Preferably, the plurality of optoelectronic components are arranged on the same substrate. In such an arrangement, a radiation incoupling layer may cover the sensitive areas of a plurality of photodetectors. Likewise, the at least one radiation-repellent layer may cover the edge regions of a plurality of photodetectors. For example, a plurality of radiation-repellent layers may be deposited on the radiation incoupling layer or on the substrate in a manner laterally offset from one another. A first radiation-repellent layer may then cover, for example, a first portion of the edge region of a plurality of photodetectors, and a second radiation-repellent layer arranged laterally offset from the first may cover a second portion of the edge region of the same plurality of photodetectors.

During production of an optoelectronic component according to the invention, a radiation incoupling layer and a radiation-repellent layer are inseparably bonded to one another by means of a coating method—for example, thermal vapor deposition. Only then is the optoelectronic component encapsulated.

The optoelectronic component according to the invention or the arrangement of optoelectronic components according to the invention is preferably used to detect electromagnetic radiation in the visible and NIR wavelength range (wavelengths between 380 and 3,000 nm).

The invention will be explained below by means of exemplary embodiments and with reference to figures, without being limited thereto. In the figures:

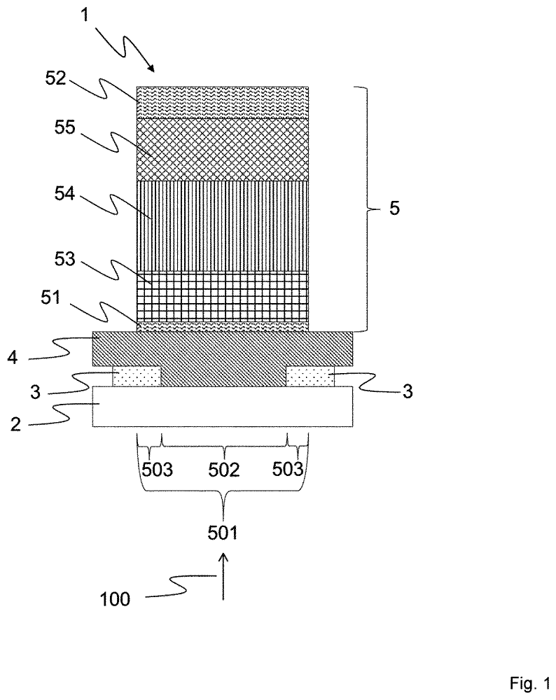

FIG. 1 is a schematic side view of the layer stack of an optoelectronic component according to the invention illuminated through the substrate and the bottom electrode (bottom illumination);

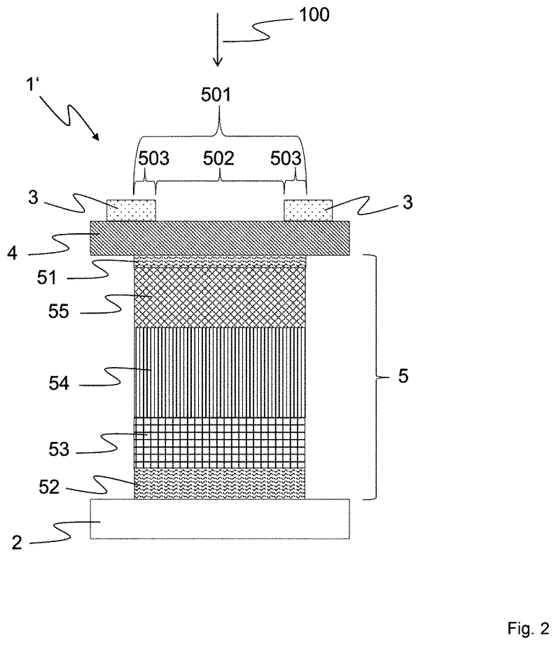

FIG. 2 is a schematic side view of the layer stack of an optoelectronic component according to the invention illuminated through the top electrode (top illumination);

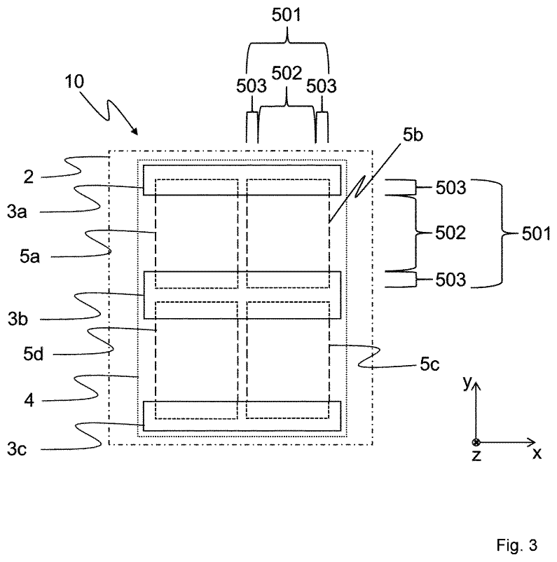

FIG. 3 is a schematic plan view of a grid-like arrangement of four optoelectronic components according to the invention;

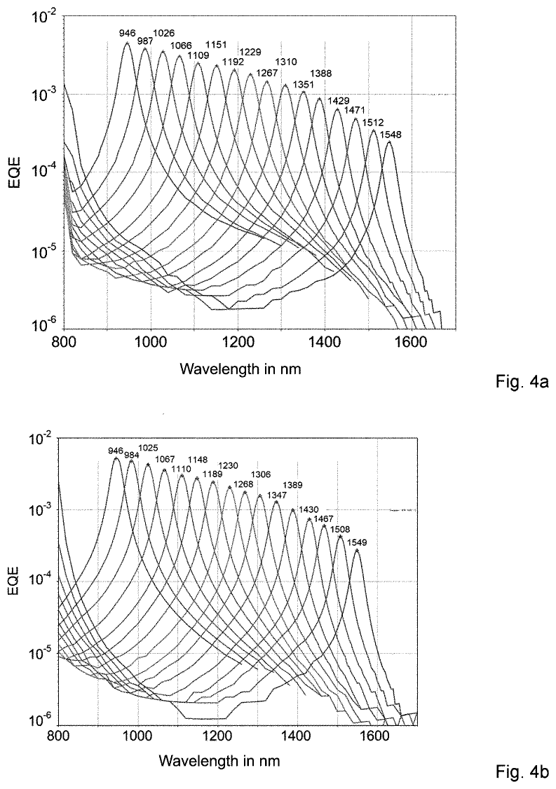

FIG. 4 is a comparison of measurements of the EQE on a first grid-like arrangement of 16 optoelectronic components according to the invention with different wavelengths to be detected, on the one hand without a radiation incoupling layer and without an integrated aperture mask (FIG. 4a), and on the other hand with a radiation incoupling layer and with an integrated aperture mask (FIG. 4b);

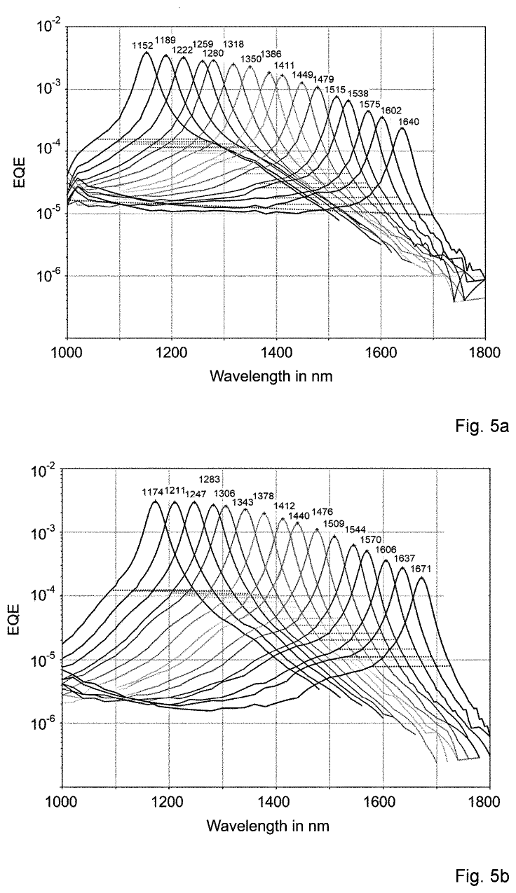

FIG. 5 is a comparison of measurements of the EQE on a second grid-like arrangement of 16 optoelectronic components according to the invention with different wavelengths to be detected, on the one hand with a radiation incoupling layer and without an integrated aperture mask (FIG. 5a), and on the other hand with a radiation incoupling layer and with an integrated aperture mask (FIG. 5b).

FIG. 1 is a side view of an optoelectronic component 1 with bottom illumination. The optoelectronic component 1 is designed as a layer stack. The optoelectronic component 1 is illuminated through the substrate 2 in the illumination direction 100 by means of an illumination source (not shown) following interaction with the sample to be examined (not shown). The substrate 2, which may for example be a glass or plastic or silicon substrate, is accordingly designed to be transparent for the electromagnetic radiation impinging on the optoelectronic component 1 with wavelengths to be detected—for example, wavelengths in the NIR range of the electromagnetic spectrum.

Two radiation-repellent metallic layers 3, which are arranged laterally offset from one another and are formed, for example, of aluminum with a thickness of 200 nm, are vapor-deposited onto regions of the substrate 2. Arranged between the radiation-repellent layers 3 and the photodetector 5 is a radiation incoupling layer 4, which consists of an organic semiconductor material, e.g., the electron transport material C₆₀, and typically has a thickness on the order of 100 nm—for example, 200 nm or 500 nm. The photodetector 5 comprises a first electrode 51 (bottom electrode, electron-collecting) and a second electrode 52 (top electrode, hole-collecting), between which there are arranged, following one another in the illumination direction 100, an electron transport layer (ETL) 53, the photoactive layer 54, and a hole transport layer (HTL) 55. The sensitive area 501 of the photodetector 5, which area is oriented perpendicular to the image plane, is divided into a selective area 502 and an edge region 503 surrounding the selective area 502. The radiation-repellent layer 3 is arranged at least on portions of the edge region 503 and overlaps the latter, in the context of the deposition accuracy, only in such a way that the selective area 502 is not covered. The edge region 503 may also be only partially covered by the radiation-repellent layer 3, i.e., only portions of the edge region 503 are covered, while other portions of the edge region may not be covered, in particular portions that cause only minor artefacts in the photosignal, because, for example, an electrode is arranged in front of these portions. In contrast, the radiation incoupling layer 4 covers at least the entire sensitive area 501 and overlaps the latter on all sides.

In the wavelength range to be detected, a radiation-repellent layer 3 has a degree of reflection of at least 80%, particularly preferably at least 90%, very particularly preferably at least 95%, so that most of the electromagnetic radiation that impinges on the region of the optoelectronic component 1 in which a radiation-repellent layer 3 is arranged will be reflected, and thus does not impinge on the layers arranged after the radiation-repellent layer 3, in particular does not impinge on the photoactive layer 54.

In the optoelectronic component 1′ illustrated in FIG. 2, the top electrode acts as the first electrode 51 and the bottom electrode acts as the second electrode 52, i.e., the optoelectronic component 1′ is illuminated through the top electrode 51 in the illumination direction 100. The radiation incoupling layer 4 is deposited on the top electrode 51 and covers at least the entire sensitive area 501. The radiation incoupling layer 4 may comprise, for example, the hole transport material BF-DPB. The photoactive layer 54 is arranged between the two electrodes 51, 52 of the photodetector 5. The photodetector 5 contains a hole transport layer (HTL) 55 between the photoactive layer 54 and the hole-collecting top electrode 55 and contains an electron transport layer (ETL) 53 between the electron-collecting bottom electrode 52 and the photoactive layer 54. The two radiation-repellent layers 3 are arranged laterally offset from one another on the radiation incoupling layer 4 and cover only two portions of the edge region 503 of the photodetector 5, beyond which they project slightly in the lateral direction, but, in the context of the deposition accuracy, not in the direction of the selective area 502. The photoactive layer 54 is therefore illuminated only beneath the selective area 502, and not beneath the edge region 503.

An optoelectronic component according to the invention with top illumination may comprise, for example, the following sequence of layers in the specified thicknesses (listed opposite to the illumination direction):

substrate (1.1 mm glass)—opaque bottom electrode with mirror surface (3 nm MoO₃—1 nm Au—100 nm Ag)—ETL (50 nm n-doped C₆₀—photoactive layer (300 nm C₆₀:ZnPc)—HTL (50 nm p-doped MeO-TPD)—partially transparent top electrode (3 nm MoO₃—1 nm Au—20 nm Ag)—radiation incoupling layer (200 nm C₆₀)—radiation-repellent layer (200 nm Al).

Once deposition is complete, the layer sequence is sealed off from the environment by means of a cover glass in an inert atmosphere.

FIG. 3 is the plan view in the illumination direction (z-direction, into the plane of the drawing) of a 2×2 arrangement 10 of four photodetectors 5a, 5b, 5c, 5d with top illumination on the same substrate 2. The sensitive areas 501 of all four photodetectors 5a, 5b, 5c, 5d are completely covered by a common radiation incoupling layer 4, which projects laterally beyond the four photodetectors 5a, 5b, 5c, 5d in all directions (x, −x, y, −y). The sensitive area 501 of each photodetector 5a, 5b, 5c, 5d is divided into a selective area 502 and a frame-like edge region 503 surrounding the selective area 502, as illustrated by way of example for the photodetector 5b on the top right. Three radiation-repellent layers 3a, 3b, 3c are arranged on the common radiation incoupling layer 4. The radiation-repellent layer 3a covers a first of the portions, extending in the x-direction, of the edge region 503 of the two photodetectors 5a and 5b arranged laterally offset from one another in the x-direction and projects beyond said portion in the x-, −x-, and −y-directions such that the selective area 502 of the photodetectors 5a and 5b, in the context of the deposition accuracy, is not covered, but, rather, is completely illuminated. The radiation-repellent layer 3c covers a first of the portions, extending in the x-direction, of the edge region 503 of the two photodetectors 5c and 5d arranged laterally offset from one another in the x-direction and projects beyond said portion in the x-, −x-, and y-directions such that the selective area 502 of the photodetectors 5c and 5d, in the context of the deposition accuracy, is not covered, but, rather, is completely illuminated. The radiation-repellent layer 3b covers a second of the portions, extending in the x-direction, of the edge region 503 of all the photodetectors 5a, 5b, 5c, 5d and projects beyond said portion in the x-and-x- directions and also in the y-direction for the photodetectors 5cand 5d and in the −y-direction for the photodetectors 5a and 5b, without, in the context of the deposition accuracy, covering the selective area 502 of the photodetectors 5a, 5b, 5c, 5d. The portion of the edge region 503 of the photodetectors 5a, 5b, 5c, 5d that extends in the y-direction is not covered by radiation-repellent layers in FIG. 3, since the top electrode is arranged at least partially in front of this portion, as a result of which the portion that extends in the y-direction causes significantly fewer artefacts than the portion of the edge region that extends in the x-direction and that is not covered by the top electrode. It will be understood that covering this portion of the edge region 503 is also in the sense of the invention.

FIGS. 4a and 4b show measurements of the EQE as a function of the wavelength on a first grid-like arrangement of 16 optoelectronic components, wherein each of the components is optimized for a different wavelength to be detected, i.e., the EQE has a maximum at a different wavelength for each optoelectronic component, i.e., in total, at the 16 different wavelengths indicated in the two figures. FIG. 4a shows measurements of the EQE of an arrangement without a radiation incoupling layer and without a radiation-repellent layer, i.e., without an integrated aperture mask. FIG. 4b shows measurements of the EQE of the same arrangement with a radiation incoupling layer that completely covers the entire arrangement, i.e., the sensitive area of each of the 16 photodetectors of the associated optoelectronic components, and a plurality of radiation-repellent layers that each cover portions of the edge region of a plurality of photodetectors of the associated optoelectronic components. The comparison of FIGS. 4a and 4b shows, on the one hand, that the EQE maximum for all the optoelectronic components is higher in FIG. 4b than in FIG. 4a, which can be interpreted as an effect of the radiation incoupling layer. The increase is between 7% in the case of optoelectronic components designed for a lower wavelength to be detected and 40% in the case of optoelectronic components designed for a higher wavelength to be detected. On the other hand, the comparison shows that, in particular, the artefacts visible in FIG. 4a in the EQE curves at low wavelengths are mitigated by an integrated aperture mask as in FIG. 4b.

This effect can be seen even more clearly when comparing FIGS. 5a and 5b. The two figures show measurements of the EQE as a function of the wavelength on a second grid-like arrangement of 16 optoelectronic components, wherein each of the components is optimized for a different wavelength to be detected, i.e., the EQE has a maximum at a different wavelength for each optoelectronic component, i.e., in total, at the 16 different wavelengths indicated in the two figures. In the arrangement of FIG. 5a, a common radiation incoupling layer completely covers the sensitive areas of all 16 photodetectors of the associated optoelectronic components. In FIG. 5b, a plurality of radiation-repellent layers are additionally arranged on the radiation incoupling layer such that portions of the edge region of all 16 photodetectors of the associated optoelectronic components are covered. The measurements shown in FIG. 5b show a significantly reduced EQE at low wavelengths. The shoulder at low wavelengths, which is visible in FIG. 5a and is caused by layer thickness inhomogeneities in the edge region, can therefore be significantly mitigated by using an integrated aperture mask, as can be seen in FIG. 5b.

### REFERENCE SIGNS

1 optoelectronic component (bottom illumination)
1′ optoelectronic component (top illumination)
10 arrangement of a plurality of optoelectronic components
100 illumination direction
2 substrate
3, 3a, 3b, 3c radiation-repellent layer
4 radiation incoupling layer
5, 5a, 5b, 5c, 5d photodetector
501 sensitive area of the photodetector
502 selective area of the photodetector
503 edge region of the photodetector
51 first electrode
52 second electrode
53 electron transport layer (ETL)
54 photoactive layer
55 hole transport layer (HTL)

1. An optoelectronic component (1, 1′), comprising a photodetector (5) having a sensitive area (501) which is formed of a selective area (502) and an edge region (503) surrounding the selective area (502), wherein the photodetector (5) comprises at least one photoactive layer (54) between two spaced-apart electrodes (51, 52), wherein the first electrode (51), which is arranged in front of the second electrode (52) in the illumination direction (100), is at least semi-transparent for electromagnetic radiation with wavelengths to be detected,
characterized in that
arranged in front of the photodetector (5) is at least one radiation incoupling layer (4), which completely covers the sensitive area (501) of the photodetector (5), and
arranged in front of the at least one radiation incoupling layer (4) is at least one radiation-repellent layer (3), which is integrally bonded to the radiation incoupling layer (4) and covers at least portions of the edge region (503) of the photodetector (5), but not more than 30% of the selective area (502) thereof, in a shielding manner against electromagnetic radiation with wavelengths to be detected.

2. The optoelectronic component (1, 1′) according to claim 1, characterized in that the radiation-repellent layer (3) is inseparably bonded to the radiation incoupling layer (4) by means of a coating method.

3. The optoelectronic component (1, 1′) according to claim 1, characterized in that the at least one radiation-repellent layer (3) contains a dielectric material.

4. The optoelectronic component (1, 1′) according to claim 1, characterized in that the at least one radiation-repellent layer (3) contains a metal.

5. The optoelectronic component (1, 1′) according to claim 1, characterized in that the at least one radiation incoupling layer (4) contains an organic semiconductor material.

6. The opptoelectronic component (1, 1′) according to claim 1, characterized in that the optoelectronic component (1, 1′) is sealed off with respect to the environment by means of an encapsulation.

7. The optoelectronic component (1, 1′) according to claim 1, characterized in that the radiation-repellent layer (3) covers not more than 20% of the selective area (502) of the optoelectronic component (1, 1′), preferably not more than 10%.

8. An arrangement (10) of at least two optoelectronic components (1, 1′) according to claim 1, which are laterally offset from one another, each comprising at least one photodetector (5a, 5b, 5c, 5d) on the same substrate (2), wherein a radiation incoupling layer (4) completely covers the sensitive area (501) of at least two of the photodetectors (5a, 5b, 5c, 5d) of the associated optoelectronic components (1, 1′) of the arrangement (10), and a radiation-repellent layer (3) covers portions of the edge region (503) of at least two of the photodetectors (5a, 5b, 5c, 5d) of the associated optoelectronic components (1, 1′) of the arrangement (10).

9. A method for producing an optoelectronic component (1, 1′) according to claim 2, characterized in that the at least one radiation-repellent layer (3) and the at least one radiation incoupling layer (4) are inseparably bonded to one another by means of a coating method.

10. A method for detecting electromagnetic radiation with wavelengths in the visible range and/or in the NIR range, the method comprising detecting said electromagnetic radiation with:
the optoelectronic component (1, 1′) according to claim 1; or
an arrangement (10) of at least two optoelectronic components (1, 1′) according to claim 1, which are laterally offset from one another, each comprising at least one photodetector (5a, 5b, 5c, 5d) on the same substrate (2), wherein a radiation incoupling layer (4) completely covers the sensitive area (501) of at least two of the photodetectors (5a, 5b, 5c, 5d) of the associated optoelectronic components (1, 1′) of the arrangement (10), and a radiation-repellent layer (3) covers portions of the edge region (503) of at least two of the photodetectors (5a, 5b, 5c, 5d) of the associated optoelectronic components (1, 1′) of the arrangement (10).

11. The optoelectronic component (1, 1′) according to claim 2, characterized in that the at least one radiation-repellent layer (3) contains a dielectric material.

12. The optoelectronic component (1, 1′) according to claim 2, characterized in that the at least one radiation-repellent layer (3) contains a metal.

13. The optoelectronic component (1, 1′) according to claim 3, characterized in that the at least one radiation incoupling layer (4) contains an organic semiconductor material.

14. The optoelectronic component (1, 1′) according to claim 11, characterized in that the at least one radiation incoupling layer (4) contains an organic semiconductor material.

15. The optoelectronic component (1, 1′) according to claim 12, characterized in that the at least one radiation incoupling layer (4) contains an organic semiconductor material.

16. The optoelectronic component (1, 1′) according to claim 2, characterized in that the optoelectronic component (1, 1′) is sealed off with respect to the environment by means of an encapsulation.

17. The optoelectronic component (1, 1′) according to claim 3, characterized in that the optoelectronic component (1, 1′) is sealed off with respect to the environment by means of an encapsulation.

18. The optoelectronic component (1, 1′) according to claim 14, characterized in that the optoelectronic component (1, 1′) is sealed off with respect to the environment by means of an encapsulation.

19. The optoelectronic component (1, 1′) according to claim 15, characterized in that the optoelectronic component (1, 1′) is sealed off with respect to the environment by means of an encapsulation.

20. The optoelectronic component (1, 1′) according to claim 1, characterized in that the radiation-repellent layer (3) covers not more than 10% of the selective area (502) of the optoelectronic component (1, 1′).
